(19) United States
(12) Patent Application Publication
(10) Pub. No.: US 2025/0358944 A1
(43) Pub. Date: Nov. 20, 2025

(54) ELECTRONIC DEVICE LOCK BRACKET AND ASSEMBLY

(71) Applicant: Cathern J. Frantz Durand, Hartland, WI (US)

(72) Inventor: Cathern J. Frantz Durand, Hartland, WI (US)

(21) Appl. No.: 19/200,286

(22) Filed: May 6, 2025

Related U.S. Application Data
(60) Provisional application No. 63/648,317, filed on May 16, 2024.

(51) Int. Cl. H05K 5/02

(52) U.S. Cl. CPC H05K 5/0221; H05K 5/0234

(57) ABSTRACT

An electronic device lock bracket provides an additional deterrent to theft of the electronic device without having to modify the existing electronic device or the cradle the electronic device is normally mounted to. The electronic device lock bracket is a generally squared U-shaped structure. It has a flat center portion and opposing end portions, each bent at a 90° angle. Each end portion is intended to be secured to each end of the manufacturer's provided bracket. Disposed centrally of the flat center portion is (1) a bent over latch cover, (2) a pair of protrusions that flank either side of a latch release, or (3) both. The latch cover is intended to prevent upward movement of a latch disposed to the rear of the electronic device and to the rear of the cradle. The protrusions are provided to prevent depression of a latch release.

This application claims priority to U.S. Provisional Patent Application No. 63/648,317 filed May 16, 2024.

### FIELD OF THE INVENTION

The present invention relates generally to locks and other security devices. It also relates generally to electronic devices. More specifically, it relates to a lock bracket that is used to secure a particular type of electronic device comprising a control and display console (“electronic device” or “console”) to a cradle and mounting bracket. As provided by the original equipment manufacturer (or “OEM”), the electronic device is provided with a “quick release” mechanism for removing it (and thereby electronically disconnecting it) from the cradle. The electronics device can be safely stowed away and then easily replaced to its operational location as desired or required.

### BACKGROUND OF THE INVENTION

There are many types of electronic devices, equipment and instruments (individually and generically, “electronic device”), such as fish finders, marine sonar devices, global positioning devices (“GPS”), among others, mounted to water craft used in the recreational sector, police and fire rescue, United States Coast Guard and other boating industries. These electronic devices are typically expensive, high-end pieces of equipment designed to be installed into the face of a dashboard of a boat or within a support bracket mounted to the dashboard or bow of the water craft. Either type of mounting allows the boater to view a control and display console that is part of the electronic device. Fasteners are typically provided by the OEM for the bracketed style of electronic device, which bracketing has a squared off and U-shaped bracket with threaded holes in opposing sides of the body of the electronic device, such holes aligning with those of support bracket uprights. Fasteners are used to secure the electronic device within an electronic device receiving cradle such that the viewing screen of the electronic device is fixable but also variably tiltable for viewing preferences along the two opposing but axially aligned fasteners. By tightening the fastener or fasteners, the electronic device can then be fixed in both the vertical position and its angle of tilt can be changed as desired or required by the boater.

In this inventor's experience, boaters typically prefer electronic devices of this nature to be raised off the dashboard or other surface so they are more readily visible from a standing position, such as when the boat driver is standing at the vessel's steering wheel, at the bow of the boat or elsewhere so that the display of the electronic device can be easily viewed. Unfortunately, the valuable nature of GPS units and marine sonar units also makes them highly sought after targets for thieves. To both ends, this applicant is aware of an electronics lock device that is disclosed and claimed in U.S. Pat. No. 7,243,514 entitled Method and Device for Securing an Electronic Instrument to a Bracket. Another electronics lock is disclosed and claimed in U.S. Pat. No. 10,000,945 entitled Universal Electronics Lock. Either device could be used as an alternative to the fasteners provided by the OEM. While the devices of those patents are fully functional and have achieved substantial commercial success, this applicant is aware of the need to develop another lock device in a form that is applicable to a particular type of electronic device that exists in the marketplace.

### SUMMARY OF THE INVENTION

More specifically, what is needed is a supplemental lock device that can be used to securely and inexpensively lock a particular electronic device which, for purposes of this disclosure, is a fish finder made and sold by GARMIN SWITZERLAND GMBH under the name GARMIN®. As alluded to above, the electronic device of this type and brand is secured to a generally U-shaped bracket that includes an intermediate “cradle” structure that accompanies the electronic device in the OEM package or kit together with the fasteners as previously mentioned. This can also be referred to as a “bail mount”. The control and display console physically and electronically couples to the cradle structure by means of a quick release structure. The present invention provides a device that, when used properly, helps to prevent theft of this particular type of electronic device by defeating removal of the control and display console, i.e., the electronic device, from the cradle it is mounted to.

Significantly, the electronic device lock bracket of the present invention provides for a unique locking device that serves as an additional deterrent to theft of the electronic device without having to modify the existing electronic device or the cradle the electronic device is normally mounted to. The electronic device lock bracket of the present invention is a generally squared U-shaped structure. It has a flat center portion and opposing end portions, each bent at a 90° angle. Each end portion is intended to be secured to each end of the manufacturer's provided bracket via an aperture. Disposed centrally of the flat center portion is (1) a bent over latch cover, (2) a pair of fingers that flank either side of a latch release, or (3) both. The latch cover is intended to prevent upward movement of a latch disposed to the rear of the electronic device and to the rear of the cradle. The pair of fingers is provided to prevent depression of a latch release. Further each end portion is configured so as to run flush against a rear surface of the electronic device, which prevents rotation of the electronic device lock bracket of the present invention about the manufacturer's provided cradle.

The foregoing and other features of the electronic device lock bracket of the present invention will be apparent from the detailed description that follows.

### BRIEF DESCRIPTION OF THE DRAWINGS

FIG. 1 is a front and right-side perspective view of an OEM electronics bracket and cradle that has the electronics device attached to it, both of which are of the type with which the electronic device lock bracket of the present invention is used.

FIG. 2 is a rear and right-side perspective view of the electronic device, cradle and mounting bracket, all attached, as illustrated in FIG. 1.

FIG. 3 is an exploded rear and right-side perspective view that is similar to FIG. 2 but also illustrating an electronic device lock bracket constructed in accordance with the present invention.

FIG. 4 is another right and right-side perspective view that is similar to FIGS. 2 and 3 and showing the electronics device lock bracket as installed on the OEM bracket, cradle and electronic device.

FIG. 5 is a right side and rear perspective view of the electronic device lock bracket constructed in accordance with the present invention.

FIG. 6 is a right side and front perspective view of the electronic device lock bracket shown in FIG. 5.

FIG. 7 is a rear elevational view of the electronic device lock bracket constructed in accordance with the present invention and showing the latch release of the electronic device in phantom view.

FIG. 8 is an enlarged rear elevational view of the central portion of the electronic device lock bracket shown in FIG. 7 and taken along line 8-8 of FIG. 7 and including a partially sectioned phantom view of the latch release of the electronic device.

FIG. 9 is a further enlarged right side elevational view of the electronic device lock bracket shown in FIGS. 7 and 8 and showing the aperture formed in the side portion of the electronic device lock bracket.

FIG. 10 is a view similar to FIG. 3 but showing an alternative embodiment of the electronic device lock bracket.

FIG. 11 is a right side and rear perspective view of the alternative embodiment of the electronic device lock bracket constructed in accordance with the present invention.

FIG. 12 is a right side and front perspective view of the electronic device lock bracket shown in FIG. 11.

FIG. 13 is a further enlarged right side elevational view of the electronic device lock bracket shown in FIGS. 11 and 12 and showing the aperture formed in the side portion of the electronic device lock bracket.

FIG. 14 is a perspective view of an alternative embodiment of the electronic device lock bracket in accordance with the present invention, the electronic device lock bracket having an aperture formed as a hole.

FIG. 15 is a perspective view of the alternative embodiment of the electronic device lock bracket shown in FIG. 14, the electronic device lock bracket having an aperture formed as a slot.

### DETAILED DESCRIPTION OF THE INVENTION

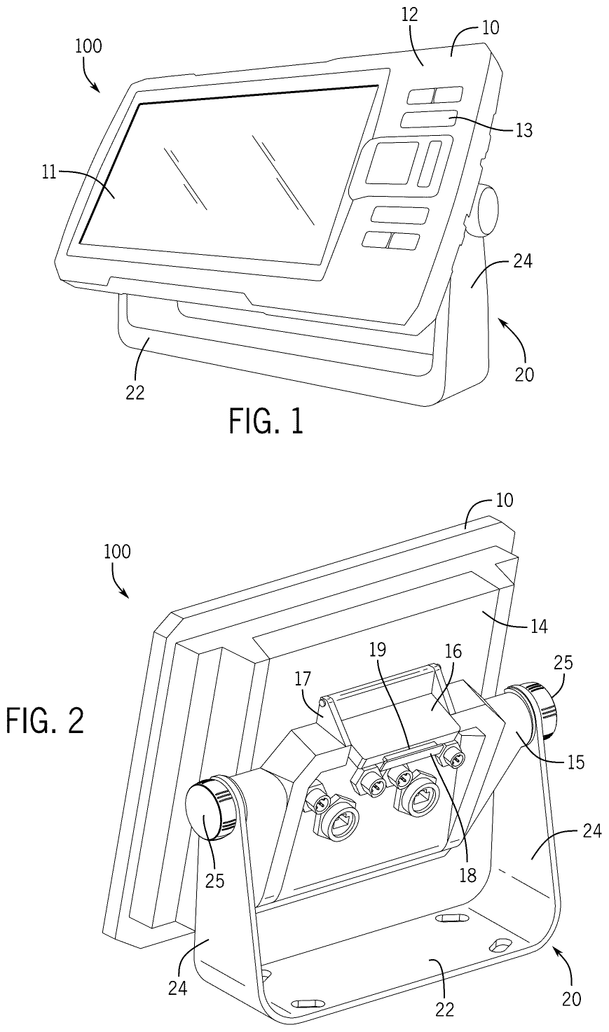

Referring now to the drawings in detail, wherein like numbered elements correspond to like elements throughout, FIG. 1 is a front and right side perspective view of an electronic device assembly, generally identified 100, of the type with which the electronic device lock bracket of the present invention is used. FIG. 2 also shows the OEM control and display console or electronic device 10, cradle 15 and bracket 20, provided with the electronic device assembly 100 from the manufacturer. In this case, the electronic device assembly 100 is a “fish finder” but the invention is not so limited. The electronic device 10 has a front face 12 with a screen display 11 and a plurality of control elements 13. Referring to FIG. 2, it shows the rear face 14 of the electronic device 10.

The cradle 15 comprises, a flip-up latch 16 and a latch release 18. The latch 16 is flanked by opposing latch support members 17. To remove the control and display console 10 from the cradle 15, the latch release 18 may be pushed inwardly and toward the control and display console 10 to release the latch 16. The latch 16 is then rotated upwardly and the control and display console 10 may be removed from the cradle 15.

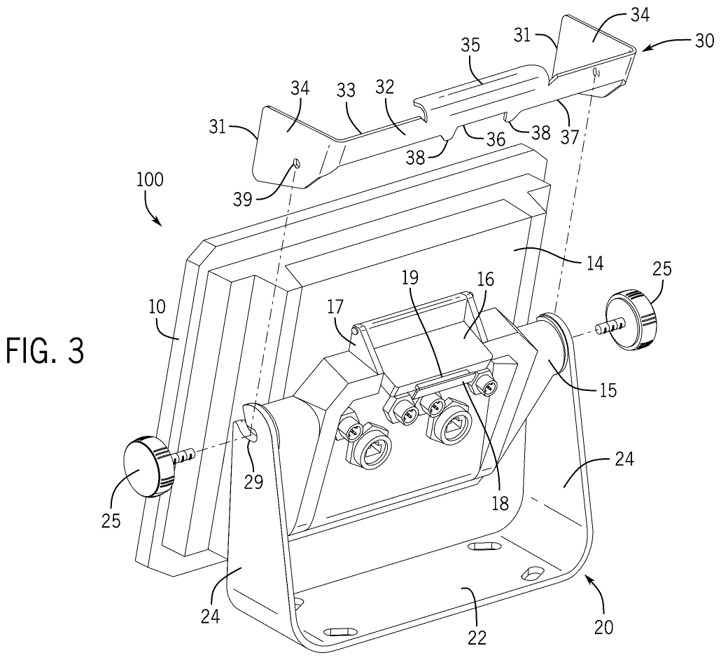

Also shown in FIG. 2 is the OEM bracket 20 which comprises a generally U-shaped structure having a center mounting portion 22 and a pair of opposing legs 24 that extend upwardly at about a right angle relative to the center mounting portion 22 at the ends of the center mounting portion 22. Lastly, it will be seen that the cradle 15 is secured to the opposing legs 24 via a pair of axially aligned fasteners 25. See also FIG. 3 in this regard.

FIG. 3 shows somewhat of an exploded view of the electronic device assembly 100, the OEM bracket 20 and the electronic device lock bracket, generally identified 30, constructed in accordance with the present invention. As shown, the electronic device lock bracket 30 comprises a central flat portion 32 having a top edge 33 and a bottom edge 37. Each end 34 of the electronic device lock bracket 30 is bent at about a 90° angle relative to the central flat portion 32. Each end 34 further comprises an aperture 39 and a front edge 31. Extending upwardly from the top edge 33 of the electronic device lock bracket 30 is an arcuate structure 35 that is bent forwardly of the electronic device lock bracket 30. Extending downwardly from the bottom edge 37 is a pair of protrusions 38. The distance between the protrusions 38 matches the width of the innermost portion 19 of the latch release 18.

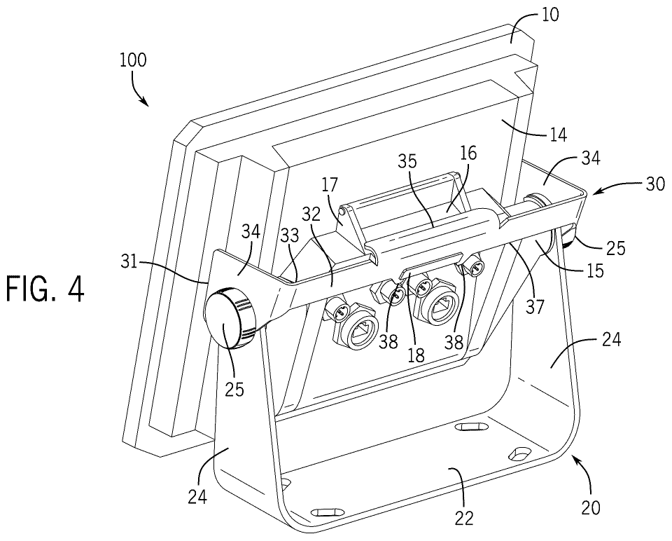

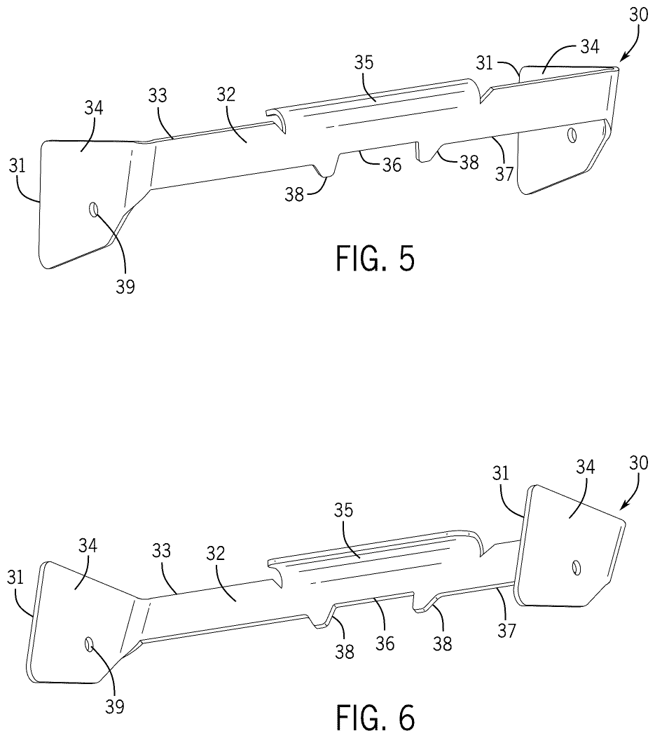

FIG. 4 illustrates the electronic device 10, the OEM bracket 20, and the electronic device lock bracket 30, when each is coupled together. As will be appreciated from the aforementioned portion of this disclosure, there is a “flush fit” between the front edge 31 of the electronic device lock bracket 30 and a planar back surface of the rear face 14 of the electronic device 10. That is, the ends 34 of the electronic device lock bracket 30 are “flared” to maximize contact and stability between the front edges 31 of the ends 34 and the rear face 14 of the electronic device 10. This feature is a tampering deterrent. See also FIGS. 5 and 6.

Also shown in FIG. 4 are the two other tampering deterrents employed in the electronic device lock bracket 30 of the present invention. One of those is the arcuate structure 35 that extends upwardly from the top edge 33 and is bent forwardly of the electronic device lock bracket 30. When the electronic device lock bracket 30 is in place, this arcuate structure 35 overlays a portion of the latch 16, thereby preventing the latch 16 from being rotated upwardly and the electronic device 10 from being separated from the cradle 15.

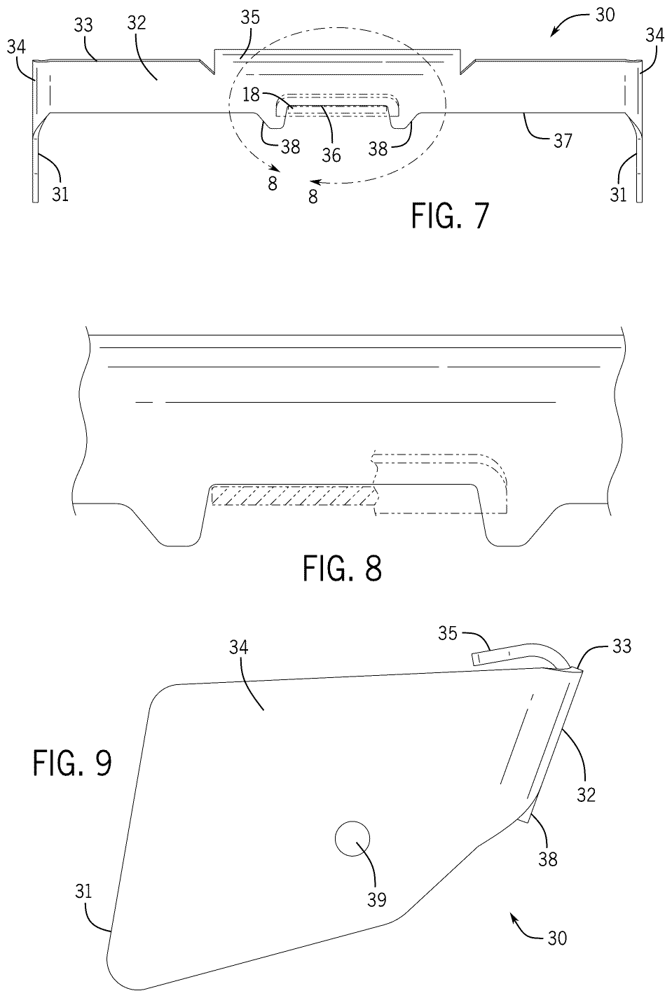

Another deterrent is the pair of protrusions 38 that extend downwardly from the edge 37 of the electronic device lock bracket 30. As mentioned earlier, the distance or spacing between the protrusions 38 substantially match the width of the innermost portion 19 of the latch release 18. When the electronic device lock bracket 30 is in place, the protrusions 38 preclude the outermost portion of the latch release 18 to be pushed inwardly. This step actually precedes the step mentioned above. That is, in order for the latch 16 to be rotated upwardly, the latch release 18 must first be pushed inwardly. By preventing the latch release 18 from being pushed in, the latch 16 cannot be rotated upwardly thereby preventing separation of the electronic device 10 from the cradle 15. See also FIGS. 7 and 8 in this regard.

While not illustrated here, it is to be understood that either one or both of the latter deterrents may be incorporated into the electronic device lock bracket 30. To optimize security, however, this applicant is of the opinion that using both of the two latter deterrents is preferable to incorporating just one or the other.

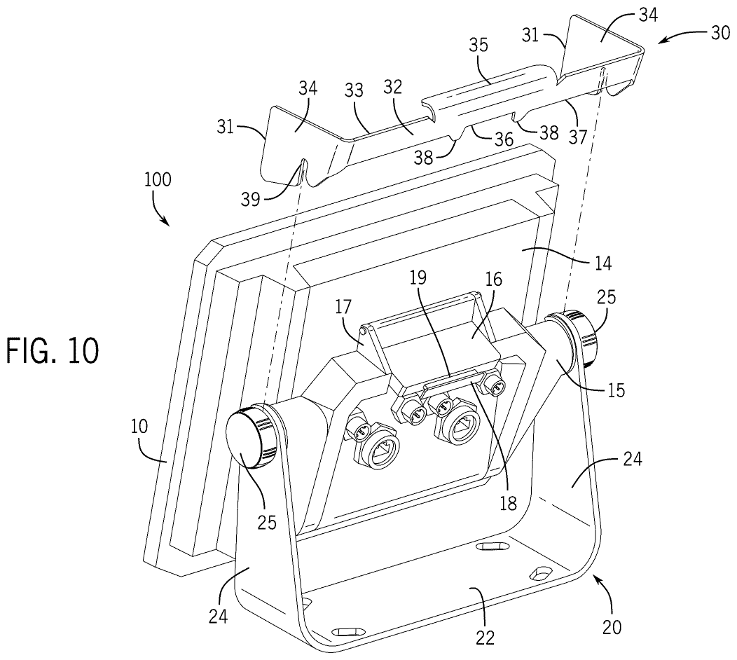

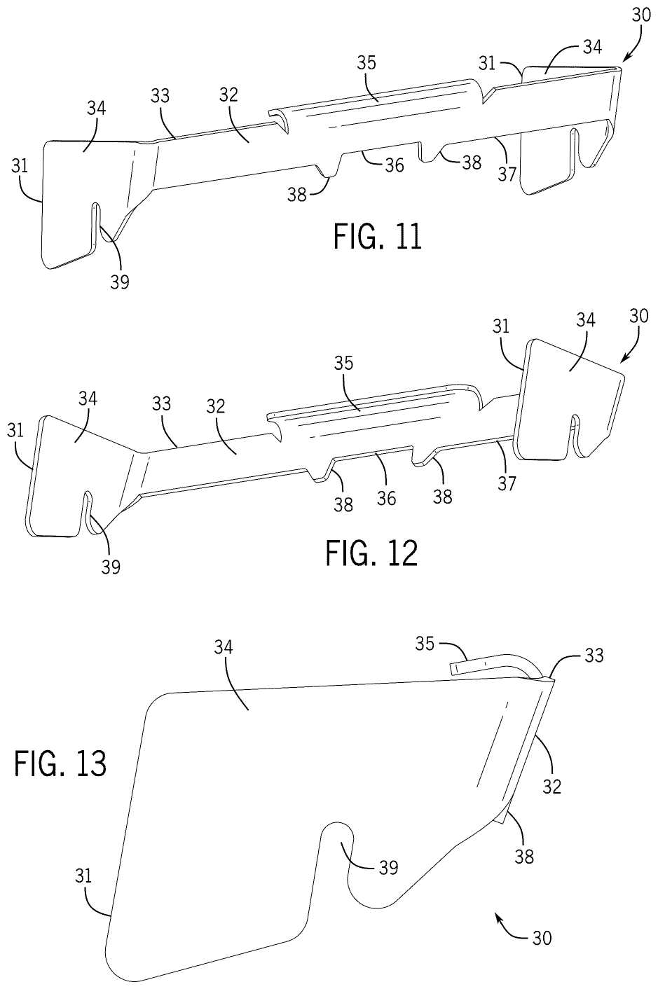

Referring now back to FIGS. 3, 5, 6 and 9, it is to be noted that the aperture 39 is a round hole. In order to use the electronic device lock bracket 30 with that configuration, the two fasteners 25 must be completely backed out of the electronics device 10. To eliminate and simplify this assembly step, an alternative embodiment of the electronic device lock bracket 30 comprises apertures 39 in the form of slide inlets. See FIGS. 10-13. In all other respects, assembly and use of the electronic device lock bracket 30 is the same.

When the electronic device lock bracket 30 referenced above is used as shown it has been noted by this applicant that the electronic device 10 cannot be placed in a position that is exactly perpendicular to the OEM bracket 20. That is, if the upwardly extending opposing legs 24 are perfectly vertical, the face of the electronic device 10 is about 5° off horizontal. There are, however, boaters who prefer to have the face of the electronic device to be in a horizontal plane for omnidirectional visibility of the screen display 11. Accordingly, this applicant has provided an alternative embodiment that is configured to allow this positioning.

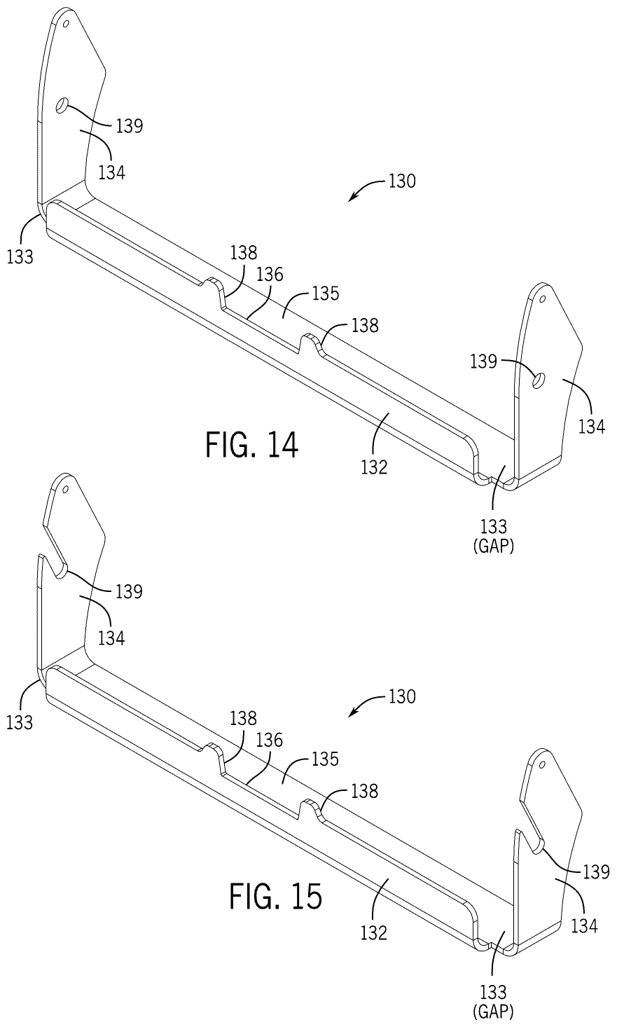

Specifically, FIGS. 14 and 15 illustrate an alternative embodiment of the electronic device lock bracket 130, the views of the bracket 130 comprising a slightly different orientation relative to the cradle 15 and the OEM bracket 20. The bracket 130 comprises a central flat portion 135 and opposing ends 134. Each end 134 of the electronic device lock bracket 130 is bent upwardly (as shown in FIG. 14, which is not the bracket's 130 installed position) at about a 90° angle relative to the central flat portion 135. Each end 134 further comprises an aperture 139. Also extending upwardly and perpendicularly from the central flat portion 135 is a flat structure 132 comprising a notch 136 disposed between a pair of protrusions 138. This is the “catch” structure for preventing the latch release 18 from being pushed into a latch-releasing position. The distance between the protrusions 138 matches the width of the innermost portion 19 of the latch release 18.

Significantly, FIGS. 14 and 15 also illustrate a “gap” 133 that is created between the central flat portion 135, the perpendicular ends 134, and the perpendicular flat structure 132. This gap 133 is provided at each end of the bracket 130 so that the upright portions 24 of the OEM bracket 20 is received within it. This allows the secured cradle 15 to be moved to a position where the electronic device 10 can be moved into a truly horizontal position for the boater. In all other respects the electronic device lock brackets 30, 130 function as intended with the tampering deterrents employed in the electronic device lock bracket 30 of the present invention also being employed in the alternative embodiment 130. Specifically, and when the electronic device lock brackets 30, 130 are in place, the elements 35, 135, respectively, overlay a portion of the latch 16, thereby preventing the latch 16 from being rotated upwardly and the electronic device 10 from being separated from the cradle 15. Similarly, the perpendicular structures 32, 132 prevent the latch release 18 from being pushed inwardly as it would be without the electronic device lock brackets 30, 130. That is, the protrusions 38, 138 preclude the outermost portion of the latch release 18 to be pushed inwardly. This step actually precedes the latch release step mentioned above. That is, in order for the latch 16 to be rotated upwardly, the latch release 18 must be pushed inwardly. By preventing the latch release 18 from being pushed inwardly, the latch 16 cannot be rotated upwardly thereby preventing separation of the electronic device 10 from the cradle 15.

Assembly and disassembly of the structures identified in this detailed description will be readily apparent to those skilled in the art. Further, additional advantages and modifications will readily occur to those skilled in the art. Therefore, the invention in its broader aspects is not limited to the specific details disclosed and described herein. Accordingly, various modifications may be made without departing from the spirit or scope of the general inventive concept.

I claim:

1. An electronic device lock bracket assembly comprising:
an electronic control and display device;
a cradle for receiving the electronic control and display device, the cradle comprising a flip-up latch, and a latch release, the flip-up latch being flanked by opposing latch support members;
wherein the latch release comprises an innermost portion having a width and an outermost portion having a width, the width of the outermost portion being greater than the width of the innermost portion;
wherein the control and display device is removable from the cradle by pushing the latch release inwardly and rotating the flip-up latch upwardly to release the latch;
a cradle bracket comprising a generally U-shaped structure having a center mounting portion and a pair of opposing legs that extend upwardly from the center mounting portion, each leg comprising an aperture, the apertures being axially aligned;
fasteners for securing the cradle to the electronic control and display device, the fasteners being axially aligned; and
an electronic device lock bracket having structure to prevent the latch release from being pushed inwardly and the flip-up latch from being rotated upwardly.

2. The electronic device lock bracket assembly of claim 1 wherein the electronic device lock bracket further comprises:
a longitudinally extending and substantially planar structure having a central flat portion with a top edge, a bottom edge, and opposing ends;
wherein the opposing ends are bent at about a right angle relative to the central flat portion of the electronic device lock bracket;
wherein each opposing end further comprises an aperture and a front edge;
a forwardly bent arcuate structure extending upwardly from the top edge of the electronic device lock bracket; and
a pair of protrusions extending downwardly from the bottom edge of the electronic device lock bracket.

3. The electronic device lock bracket assembly of claim 2 wherein the downwardly extending protrusions of the electronic device lock bracket are disposed at a distance from one another such that the protrusions capture the innermost portion of the width of the latch release when the electronic device lock bracket is attached.

4. The electronic device lock bracket assembly of claim 3 wherein the downwardly extending protrusions of the electronic device lock bracket are disposed at a distance from one another such that the width of the outermost portion is prevented from passing between latch protrusions when the electronic device lock bracket is attached.

5. The electronic device lock bracket assembly of claim 4 wherein the forwardly bent arcuate structure of the of the electronic device lock bracket overlays the flip-up latch when the electronic device lock bracket is attached.

6. The electronic device lock bracket assembly of claim 5 wherein the opposing ends of the electronic device lock bracket comprise axially-aligned apertures for attachment.

7. The electronic device lock bracket of claim 6 wherein at least one of the apertures comprises a slot.

8. An electronic device lock bracket for use with an electronic device lock bracket assembly, the assembly comprising a cradle for receiving an electronic control and display device, the cradle comprising a flip-up latch, and a latch release, the flip-up latch being flanked by opposing latch support members; wherein the latch release comprises an innermost portion having a width and an outermost portion having a width, the width of the outermost portion being greater than the width of the innermost portion; and wherein the electronic control and display device is removable from the cradle by pushing the latch release inwardly and rotating the flip-up latch upwardly to release the latch; the bracket comprising structure that prevents the latch release from being pushed inwardly and the flip-up latch from being rotated upwardly to keep an electronic control and display device secured to the cradle and prevent removal of the device from the cradle.

9. The electronic device lock bracket of claim 8 wherein the electronic device lock bracket further comprises:
a longitudinally extending and substantially planar structure having a central flat portion having a top edge, a bottom edge, and opposing ends;
wherein the opposing ends are bent at about a right angle relative to the central flat portion of the electronic device lock bracket;
wherein each opposing end further comprises an aperture and a front edge;
a forwardly bent arcuate structure extending upwardly from the top edge of the electronic device lock bracket; and
a pair of protrusions extending downwardly from the bottom edge of the electronic device lock bracket.

10. The electronic device lock bracket of claim 9 wherein the downwardly extending protrusions of the electronic device lock bracket are disposed at a distance from one another such that the protrusions capture the innermost portion of the width of the latch release when the electronic device lock bracket is attached.

11. The electronic device lock bracket of claim 10 wherein the downwardly extending protrusions of the electronic device lock bracket are disposed at a distance from one another such that the width of the outermost portion is prevented from passing between latch protrusions when the electronic device lock bracket is attached.

12. The electronic device lock bracket of claim 11 wherein the forwardly bent arcuate structure of the electronic device lock bracket overlays the flip-up latch when the electronic device lock bracket is attached.

13. The electronic device lock bracket of claim 12 wherein the opposing end apertures are axially-aligned.

14. The electronic device lock bracket of claim 13 wherein at least one of the apertures comprises a slot.

15. An electronic device lock bracket for use with an electronic device lock bracket assembly, the assembly comprising a cradle for receiving an electronic control and display device, the cradle comprising a flip-up latch, and a latch release, the flip-up latch being flanked by opposing latch support members; wherein the latch release comprises an innermost portion having a width and an outermost portion having a width, the width of the outermost portion being greater than the width of the innermost portion; and wherein the control and display device is removable from the cradle by pushing the latch release inwardly and rotating the flip-up latch upwardly to release the latch; the bracket comprising structure that prevents the latch release from being pushed inwardly and the flip-up latch from being rotated upwardly to keep an electronic control and display device secured to the cradle and prevent removal of the device from the cradle.

16. The electronic device lock bracket of claim 15 wherein the electronic device lock bracket further comprises:
a longitudinally extending and substantially planar structure having a central flat portion having a top edge, a bottom edge, and opposing ends;
wherein the opposing ends are bent at about a right angle relative to the central flat portion of the electronic device lock bracket;
wherein each opposing end further comprises an aperture and a front edge; and
a forwardly bent arcuate structure extending upwardly from the top edge of the electronic device lock bracket.

17. The electronic device lock bracket of claim 16 wherein the forwardly bent arcuate structure of the of the electronic device lock bracket overlays the flip-up latch when the electronic device lock bracket is attached.

18. The electronic device lock bracket of claim 16 wherein the opposing end apertures are axially-aligned.

19. The electronic device lock bracket of claim 17 wherein at least one of the apertures comprises a slot.

20. An electronic device lock bracket for use with an electronic device lock bracket assembly, the assembly comprising a cradle for receiving an electronic control and display device, or electronic device, the cradle comprising a flip-up latch, and a latch release, the flip-up latch being flanked by opposing latch support members; wherein the latch release comprises an innermost portion having a width and an outermost portion having a width, the width of the outermost portion being greater than the width of the innermost portion; and wherein the control and display device is removable from the cradle by pushing the latch release inwardly and rotating the flip-up latch upwardly to release the latch; the bracket comprising structure that prevents the latch release from being pushed inwardly and the flip-up latch from being rotated upwardly to keep an electronic control and display device secured to the cradle and prevent removal of the device from the cradle.

21. The electronic device lock bracket of claim 20 wherein the electronic device lock bracket further comprises:
a longitudinally extending and substantially planar structure having a central flat portion having a top edge, a bottom edge, and opposing ends;
wherein the opposing ends are bent at about a right angle relative to the central flat portion of the electronic device lock bracket;
wherein each opposing end further comprises an aperture and a front edge; and
a pair of protrusions extending downwardly from the bottom edge of the electronic device lock bracket.

22. The electronic device lock bracket of claim 21 wherein the downwardly extending protrusions of the electronic device lock bracket are disposed at a distance from one another such that the protrusions capture the innermost portion of the width of the latch release when the electronic device lock bracket is attached.

23. The electronic device lock bracket of claim 22 wherein the downwardly extending protrusions of the electronic device lock bracket are disposed at a distance from one another such that the width of the outermost portion is prevented from passing between latch protrusions when the electronic lock bracket is attached.

24. The electronic device lock bracket of claim 23 wherein the opposing end apertures are axially-aligned.

25. The electronic device lock bracket of claim 24 wherein at least one of the apertures comprises a slot.
